(19) United States
(12) Patent Application Publication
(10) Pub. No.: US 2002/0086446 A1
(43) Pub. Date: Jul. 4, 2002

(54) Method for manufacturing a monolithic structure including a perovskite dielectric capacitor

(76) Inventors: Pascale Charpentier, Tours (FR); Christine Anceau, Saint Roch (FR)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 09/977,055

(22) Filed: Oct. 12, 2001

(30) Foreign Application Priority Data
Oct. 13, 2000 (FR) 00/13178

(51) Int. Cl. H01L 21/00

(52) U.S. Cl. 438/3

(57) ABSTRACT

A method for manufacturing, on a silicon substrate, a capacitor of high capacitance, including the following successive steps, coating the substrate with a first insulating layer, successively forming and etching on the substrate, a first electrode, a dielectric made of a ferroelectric material with a high dielectric constant and, a second electrode, coating the structure with a second insulating layer for encapsulating the capacitor structure, forming contact openings towards semiconductor areas and towards the first electrode of the capacitor, depositing and etching a first conductive layer, depositing a third protective insulating layer, depositing a second conductive layer establishing, in particular, a contact with the upper electrode of the component, and depositing a final passivation layer.

### BACKGROUND OF THE INVENTION

1. Field of the Invention

The present invention relates to electronic components in the form of monolithic structures incorporating active components formed in a semiconductor substrate and passive components, including capacitors, formed above this substrate.

2. Discussion of the Related Art

The forming of capacitors in monolithic structures raises bulk problems. Indeed, the capacitance of a capacitor is defined by its surface, the thickness of its dielectric and the dielectric constant of the material used. The materials currently used as dielectrics have dielectric constants smaller than 10, for example, 3.9 for silicon oxide and 7 for silicon nitride, which enables obtaining capacitors having a capacitance per unit surface area on the order of from 1 to 2 nF/mm².

To obtain capacitors of greater capacitance per unit surface area, for example, from 20 to 30 nF/mm², materials with a high dielectric constant, such as perovskites, which for example include lead titanate zirconate (Pb(ZrₓTi₁₋ₓ)O3, with x varying from 0 to 1, or PZT), barium and strontium titanate (BaSrTiO₃ or BST), strontium and barium titanate (SrBa₂TiO₉ or SBT), must be used as materials. These materials in thin layers have dielectric constants much greater than 100, which can reach values on the order of one thousand for PZT. However, the properties of these products make them extremely difficult to be used in the context of industrial processes generally used in the field of electronic component manufacturing. For example, PZT is very rapidly etched in conventional cleaning baths (H₂SO₄/H₂O₂) and lead-based components can contaminate a manufacturing line. Accordingly, the forming of monolithic structures including capacitors of strong capacitance is generally given up, especially in the context of power components, and discrete components continue being used.

### SUMMARY OF THE INVENTION

An object of the present invention is to provide a manufacturing method enabling, industrially, creation of monolithic structures including active components formed in a semiconductor substrate and various passive components on this substrate, including at least one capacitor with a high capacitance per unit surface area, in which the dielectric is a perovskite.

A more specific object of the present invention is to provide such a method compatible with the usual steps of monolithic circuit manufacturing.

To achieve these and other objects, the present invention provides a method for manufacturing a monolithic structure including, on a silicon substrate, passive components, among which a capacitor of high capacitance, including the following successive steps:

coating the substrate with a first insulating layer,

successively forming and etching on the substrate:

a first electrode,

a dielectric made of a ferroelectric material with a high dielectric constant and,

a second electrode,

coating the structure with a second insulating layer for encapsulating the capacitor structure,

forming contact openings towards semiconductor areas and towards the first electrode of the capacitor,

depositing and etching a first conductive layer,

depositing a third protective insulating layer,

depositing a second conductive layer establishing, in particular, a contact with the upper electrode of the component,

depositing a final passivation layer.

According to an embodiment of the present invention, the dielectric in a ferroelectric material is a perovskite.

According to an embodiment of the present invention, the perovskite is PZT.

According to an embodiment of the present invention, the method includes, after the step of deposition of the first conductive layer, a step of deposition of a resistive layer and of etching of this layer to form resistors between pads of the first conductive layer.

### BRIEF DESCRIPTION OF THE DRAWINGS

The foregoing objects, features and advantages of the present invention, will be discussed in detail in the following non-limiting description of specific embodiments in connection with the accompanying

FIGS. 1 to 4, which describe successive steps of manufacturing of a structure according to an embodiment of the present invention.

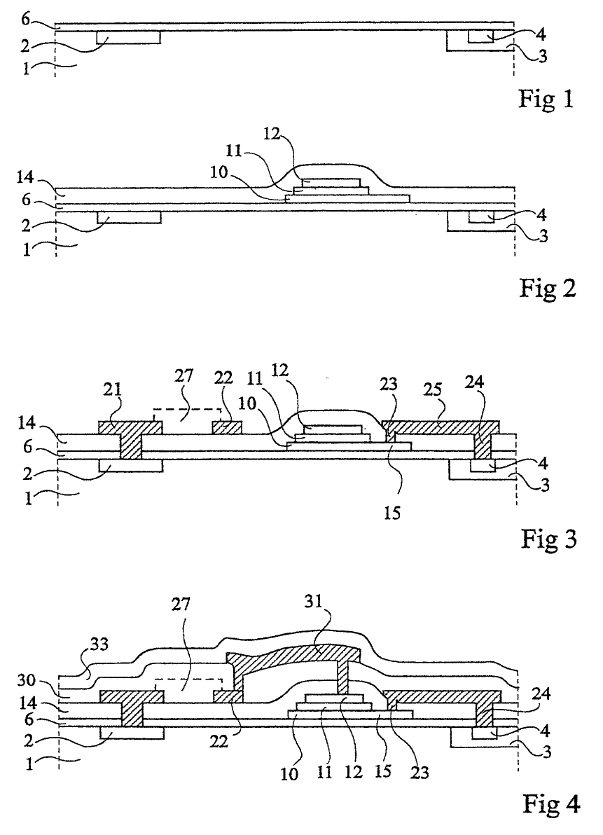

### DETAILED DESCRIPTION

A monolithic structure according to the present invention is formed on a semiconductor substrate 1, currently silicon, possibly including an upper epitaxial layer. Various regions with different dopings intended for forming active components such as diodes, bipolar transistors, field-effect transistors, or passive components such as diffused resistors are formed in this substrate. The active components may correspond to lateral structures, all electrodes of which are present on the upper substrate surface, or to vertical structures in which the rear substrate surface is metallized and corresponds to an active electrode of one or several of the components formed in the substrate. As an example, a region 2 of a conductivity type opposite to that of the substrate, for example corresponding to an electrode of a diode, and nested regions 3 and 4, region 3 for example corresponding to the base of a transistor and region 4 to its emitter, have been shown in the substrate. These structures are described herein as an example only. Generally speaking, the present invention applies to a substrate in which regions and areas adapted to forming elements of active or passive components have been formed.

The resulting structure is covered with an insulating protective layer 6, currently silicon oxide. This layer results from the method of component manufacturing in the silicon; it has a variable thickness, for example, from 0.2 to 2 μm; its thickness can be increased by adding a deposited oxide. On this protective layer, according to the present invention, a capacitor is first formed by successively depositing and etching a first conductive layer 10, an insulator 11 with a high dielectric constant and a second conductive layer 12. The first conductive layer 10 forming the first electrode or lower electrode of the capacitor is preferably metallic, of a metal adapted to tolerating an air anneal at 700° C. necessary to the forming of perovskite 11. Layer 10 may for example be formed of a titanium-platinum bilayer. Insulator 11 is a perovskite, preferably PZT. Second conductive layer 12 forming the second electrode or upper electrode of the capacitor is preferably metallic, for example made of aluminum, platinum or gold. Each of the layers is etched after its deposition to be given the desired shape.

According to an aspect of the present invention, once the three layers forming the two electrodes and the dielectric of the capacitor have been formed, the entire structure is coated with an insulating encapsulation layer 14 for avoiding that, in subsequent operations, the perovskite should be likely to be etched, to be damaged, and to pollute other areas of the structure, for example with lead in the case of PZT. The fact of encapsulating the PZT with layer 14 enables, according to a significant advantage of the present invention, keeping for the forming of the other elements in the structure conventional masking and etching methods, especially using wet etchings, as usual in the context of power component manufacturing.

Then, as shown in FIG. 3, the active portion of capacitor structure 10, 11, 12 being maintained encapsulated in protection layer 14, openings are formed and a first metallization is deposited.

For example, a contact opening is formed above semiconductor region 2, a contact opening is formed above semiconductor region 4, and a contact opening is formed above an extension 15 of lower electrode 10 of the capacitor.

A metallization is then performed, for example, to form a pad 21 for contact with semiconductor region 2, a pad 22, a pad 23 for contact with lower electrode 15, and a pad 24 for contact with semiconductor region 4. This metallization is for example aluminum. In the example shown, a connection 25 between pads 23 and 24 has been indicated. After this step, a material adapted to forming a resistor between pads 21 and 22 may be deposited. This material will for example be tantalum nitride, the tantalum nitride deposition being followed by an etch step, and during this step, the capacitor structure is still encapsulated. Given that this is an option, tantalum nitride region 27 has been shown in dotted lines in FIG. 4.

Then, a new protective insulating layer 30 in which openings for contact with various underlying elements, and especially with upper electrode 12 of the capacitor, is deposited. A second metallization 31 is then deposited (for example, aluminum) which, in the example shown, establishes a connection between pad 22 and upper electrode 12. Finally, at a final step, a passivation layer 33 (for example, PSG) may be deposited on the upper structure surface. This layer may be opened above metal pads at the locations where connections to the outside are desired to be established, for example, by welding a wire or depositing a metallization compatible with welding balls.

Thus, according to an advantage of the present invention, perovskite layer 11 and conductive layer 12 which partially covers it are encapsulated by insulating layer 14 during the entire process and only an upper portion of upper electrode 12 is exposed at the time when final contact metallization 31 is desired to be established.

The present invention is likely to have various alterations, modifications, and improvements which will readily occur to those skilled in the art, especially as concerns the insulating and protective materials. One may for example, instead or in addition to the silicon oxide, use silicon nitride, an insulating ceramic or an optical material.

Similarly, the metals used to establish the contacts may be chosen from among various materials usually used in the field, for example, of aluminum.

As another alternative of the present invention, first electrode 10 of the capacitor, instead of being deposited on insulating layer 6, may be in contact with a chosen area of substrate 1 to directly establish a contact with this area. In this case, layer 10 will extend on all sides beyond said opening so that, upon deposition and etching of PZT layer 11, no exposed surface portion can be found.

Such alterations, modifications, and improvements are intended to be part of this disclosure, and are intended to be within the spirit and the scope of the present invention. Accordingly, the foregoing description is by way of example only and only as defined in the following claims and the equivalents is not intended to be limiting. The present invention is limited thereto.

What is claimed is:

1. A method for manufacturing a monolithic structure including, on a silicon substrate, passive components, among which a capacitor of high capacitance, including the following successive steps:
coating the substrate with a first insulating layer,
successively forming and etching on the substrate:
a first electrode,
a dielectric made of a ferroelectric material with a high dielectric constant and,
a second electrode,
coating the structure with a second insulating layer for encapsulating the capacitor structure,
forming contact openings towards semiconductor areas and towards the first electrode of the capacitor,
depositing and etching a first conductive layer,
depositing a third protective insulating layer,
depositing a second conductive layer establishing, in particular, a contact with the upper electrode of the component,
depositing a final passivation layer.

2. The method of claim 1, wherein the dielectric in a ferroelectric material is a perovskite.

3. The method of claim 2, wherein the perovskite is PZT.

4. The method of claim 1, including, after the step of deposition of the first conductive layer, a step of deposition of a resistive layer and of etching of this layer to form resistors between pads of the first conductive layer.
